(19) United States
(12) Patent Application Publication
(10) Pub. No.: US 2006/0198956 A1
(43) Pub. Date: Sep. 7, 2006

(54) Chemical vapor deposition of long vertically aligned dense carbon nanotube arrays by external control of catalyst composition

(76) Inventor: Gyula Eres, Knoxville, TN (US)

Correspondence Address: UT-Battelle, LLC;Office of Intellectual Property, One Bethal Valley Road, 4500N, MS-6258, Oak Ridge, TN, 37831, US

(21) Appl. No.: 11/072,721

(22) Filed: Mar. 4, 2005

(51) Int. Cl. C23C 16/00

(52) U.S. Cl. 427/249.1; 118/715; 118/726

(57) ABSTRACT

Vertically aligned carbon nanotubes (VACNTs) of increased length are produced in a method that introduces ferrocene into an acetylene/hydrogen/inert gas stream during a chemical vapor deposition process. The ferrocene is supplied from a controllable thermal sublimation source. Independent and precise control of the ferrocene into the feedstock gas facilitates the growth of thick films comprising long carbon nanotubes on conductive substrates. An order of magnitude increase in the length of CNTs, from a few hundred microns to several mm is achieved.

### STATEMENT REGARDING FEDERALLY SPONSORED RESEARCH OR DEVELOPMENT

The United States Government has rights in this invention pursuant to Contract No. DE-AC05-00OR22725 between the United States Department of Energy and UT-Battelle, LLC.

### BACKGROUND OF THE INVENTION

1. Field of the Invention

The present invention relates to the growth of vertically aligned carbon nanotube (VACNT) arrays on predeposited metal catalyst layers by the chemical vapor deposition (CVD) process. More particularly, longer CNTs and thicker CNT films are achieved through the use of a controllable ferrocene sublimator during the growth process. The sublimator acts as a secondary source of iron atoms, and provides significant control over the growth process.

2. Description of Prior Art

Carbon nanotubes (CNTs) exhibit extraordinary physical properties that make them attractive for a wide range of novel applications from quantum electronic devices to superstrong composite materials. The main hurdle that prevents widespread practical use of CNTs is the lack of controllable and cost effective growth methods for the mass production of sufficiently pure CNTs.

Electronic device applications require CNTs to be deposited in the form of thin films preferably on conducting electrode surfaces. Chemical vapor deposition (CVD) is a simple and inexpensive growth technique that has been used extensively for producing such CNTs. CVD of CNTs is a catalytic process that is performed by thermal decomposition of a carbon feedstock. The best catalysts for CNT CVD are transition metals. These are predeposited on the conducting patterned surfaces on which the subsequent CNT growth occurs.

The most effective transition metal for catalytic growth of CNTs by CVD is iron (Fe). In addition to the active catalyst, the predeposited metal layer includes other metals that are needed to promote CNT nucleation and/or serve as a diffusion barrier in the CNT growth process. A trilayer consisting of 10 nm of Al, 1 nm of Fe, and 0.2 nm of Mo has been found to be the most effective multilayer catalyst. It is widely used in CVD CNT growth processes. The catalyst multilayer is deposited on Silicon (100) wafers by electron beam evaporation at room temperature. The CVD growth is performed in a heated quartz tube reactor using a gas mixture that includes acetylene, hydrogen and an inert gas, usually helium or argon.

CVD of CNTs on Al/Fe/Mo multilayer catalysts suffers from undesirable side effects. The first side effect is poor CNT growth. A large variation in the catalyst efficiency is caused by inadvertent variations of the nominal composition of the catalyst layers. The optimal catalyst efficiency occurs in a very narrow window of layer composition. Thickness control required to obtain such a precise catalyst composition is difficult to achieve using a simple evaporator. The inadvertent variations in the thickness of the constituent layers manifest themselves in poor CNT growth leading to low CNT yields.

The second side effect is growth stoppage. Catalyst deactivation leads to the termination of CNT growth after a few hundred microns. This effect is believed to be related to encapsulation of the active catalyst surface by fullerene (carbon) layers which deactivate the site and hinder CNT growth on such a deactivated surface. Both of these undesirable side effects are related to the composition of the catalyst layer, in particular to the content of the active iron catalyst.

In the bulk growth of CNTs, ferrocene (Fe(C₅H₅)₂) is a known source of Fe catalyst using a floating catalyst method. It is called floating because ferrocene is evaporated from either a boat or a solution to form gas phase Fe nanoparticles. The solution is prepared by dissolving ferrocene in a suitable hydrocarbon solvent that serves as feedstock upon evaporation. Benzene and toluene are typically used for this purpose.

The CVD method is also referred to as injection CVD because a syringe pump is sometimes used for dosing the solution. The drawback of both of these techniques is that the amount of ferrocene cannot be controlled. Consequently, overdosing of ferrocene occurs and the CNTs grown by these techniques have inferior properties. The CNTs contain a large amount of Fe and encapsulated Fe nanoparticles, and the CNT diameters are large, from 20 to 100 nm. In contrast, the CNT diameters obtained by the present invention are fairly uniform around 10 nm.

### REFERENCES

1. U. S. Patent Application Publication No. US 2002/0102353 A1, published Aug. 1, 2002, K. Mauthner, X. Tang, and R. Haubner.

2. U.S. Pat. No. UA 6,761,870 B1, issued Jul. 13, 2004, R. E. Smalley, K. A. Smith, D. T. Colbert, P. Nikolaev, M. J. Bronikowski, R. K. Bradley, and F. Rohmund.

3. A. Cao, X. Zhang, C. Xu, J. Liang, D. Wu, X. Chen, B. Wei, and P. M. Ajayan, Appl. Phys. Lett. 79, 1252 (2001).

4. R. Andrews, D. Jacques, D. Qian, and T. Rantell, Acc. Chem. Res. 35, 1008 (2002).

5. L. Delzeit, C. V. Nguyen, B. Chen, R. Stevens, A. Cassell, J. Han, and M. Meyyappan, J. Phys. Chem. B 106, 5629 (2002).

6. H. Hou, A. K. Schaper, F. Weller, and A. Greiner, Chem. Mater. 14, 3990 (2002).

7. H. Cui, G. Eres, J. Y. Howe, A. Puretkzy, M. Varela, D. B. Geohegan, and D. H. Lowndes, Chem. Phys. Lett. 374, 222 (2003).

8. C. Singh, M. S. P. Shaffer, and A. H. Windle, Carbon 41, 359 (2003).

### BRIEF SUMMARY OF THE INVENTION

In a preferred embodiment, a CVD method of producing a carbon nanotube film on a catalyst layer includes the steps of placing a substrate having a catalyst layer in a heatable CVD reactor; flowing a gas mixture including hydrogen and an inert gas over the catalyst layer; flowing an externally controllable amount of catalyst precursor gas over the catalyst layer; and flowing a carbon containing source gas over the catalyst layer.

In another embodiment, a heatable CVD reactor that produces a carbon nanotube film on a catalyst layer is improved by adding apparatus that comprises an externally controllable sublimation source for delivering a catalyst precursor gas to the catalyst layer.

### BRIEF DESCRIPTION OF THE DRAWINGS

FIG. 1. is an illustrative diagram of a ferrocene thermal evaporation source in accordance with the invention.

FIG. 2. is a graph showing the temperature dependence of the CNT film thickness under various growth conditions. Solid dots correspond to CVD growth on an Al/Fe/Mo multilayer using a 100 sccm/2.9 sccm hydrogen/acetylene ratio. Solid squares represent CVD growth with the addition of 4 mg/h of ferrocene. Filled triangles represent CNT growth for an optimized ratio of 4 mg/h of ferrocene to 12.4 sccm of acetylene.

FIG. 3 is a low magnification SEM image of a 3.25 mm thick CNT film in accordance with the invention.

FIG. 4 is a high resolution TEM image of a typical multiwall CNT in accordance with the invention.

FIG. 5 is a SEM image of the top of a CNT film in accordance with the invention.

FIG. 6 is a SEM image of the side wall of the CNT film of FIG. 5.

FIG. 7 is a high resolution SEM image of CNT alignment in the films of FIGS. 5 and 6.

FIG. 8 is a SEM image of alphabetical characters grown on a Si wafer. The letters are 1.5 mm tall, and the line width is 10 mm. The letters were produced by liftoff using a photolithographically defined resist pattern.

### DETAILED DESCRIPTION OF THE INVENTION

A method providing extra Fe from an externally-controlled ferrocene source and changing the catalyst composition during a CNT growth process is described. The Fe precursor is ferrocene, an organometallic molecule that upon decomposition releases one Fe atom per each molecule. Decomposition of ferrocene is induced by the metal catalyst layer and is highly surface-specific and selective. Selectivity means that CNT growth occurs only on the areas where the catalyst layer is present. The Fe atoms released by decomposition of ferrocene catalyze the decomposition of acetylene and enhance the growth of VACNTs.

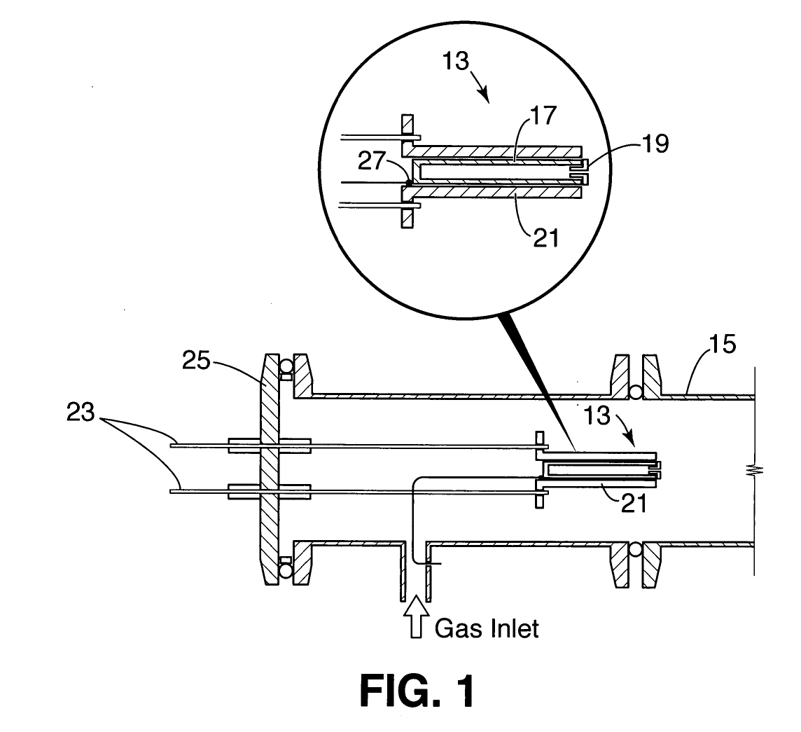

FIG. 1 illustrates the thermal evaporation source 13 for introducing ferrocene directly into the gas stream of a CVD CNT process. In FIG. 1, the ferrocene source 13 is located at the inlet 15 of a quartz tube furnace. The ferrocene is contained in a 0.22 in. diameter, 2 in. long tantalum cartridge 17. After being loaded with 200-300 mg of ferrocene, the open end of the cartridge 17 is sealed with a stainless steel plug 19 in which a 250 μm orifice has been drilled.

The cartridge 17 is heated by a 2 in. long, 0.25 in. inside diameter pyrolytic boron nitride nozzle heater 21. The heater 21 is mounted by means of its power feedthroughs 23 onto a flange 25. The temperature of the ferrocene is measured by a thermocouple 27 in contact with the cartridge 17. The transfer of ferrocene into the gas stream occurs by sublimation at temperatures slightly below the melting point of ferrocene (174° C.). By controlling the temperature of the cartridge 17, i.e., the sublimation temperature of the ferrocene, the source 13 precisely controls the amount of ferrocene introduced into the gas stream. The exact amount of ferrocene used during a CNT growth run is determined by weighing the cartridge.

The invention is not restricted to the use of ferrocene. Other organometallic compounds that produce transition metal atoms by thermal decomposition can be used. For example, cobaltocene and nickelocene could be used to supply Co and Ni.

In further detail, and by way of example, an Al/Fe/Mo layer is deposited on a silicon (Si) wafer by electron beam evaporation at room temperature. Other deposition methods could be used. The composition of the catalyst layer is controlled by controlling the layer thickness during deposition. The best catalytic effect is obtained by a 10 nm Al, 1 nm Fe, and 0.2 nm Mo trilayer. The layers are deposited in succession. The order of metal deposition could not be correlated with observable CNT growth changes. CVD of CNTs is performed by placing a piece of the Si wafer with the metal catalyst on an alumina boat, and placing the boat into a 1.5 in. diameter and 40 in. long quartz tube with a 12 in. heated region. The maximum film thickness is observed 1-2 in. from the leading edge of the hot zone and falls off with distance away from the leading edge.

The optimal growth rate depends on the composition of the feedstock. The properties of the CNTs also depend on which inert gas is used. It was observed that the adhesion to the substrate is substantially stronger when helium is used instead of argon. The optimal feedstock consists of 3 sccm of acetylene (C₂H₂), 100 sccm of hydrogen, and 500 sccm of helium. If helium is replaced with argon, the CNTs are shorter, and the films are fluffy and don't adhere well to the substrate.

The details of the temperature ramp-up are important. Heating to the growth temperature is performed in air with no gas flow. When the growth temperature is reached, the hydrogen and inert gas flow are started. This procedure was found to result in longer CNTs than if heating were performed in a flow of hydrogen and inert gas. Longer tubes are obtained because oxidation of Fe beneficially affects catalysis. The ferrocene source is started after the hydrogen and inert gas. The timing is not important. The acetylene flow is started when the source temperature reaches 145° C. This typically occurred after 8-9 mins. During this time, ferrocene flow is established and a fresh Fe layer forms on the predeposited metal catalyst layer.

Selective CNT growth occurs with catalyst patterns on Si because the deposition of Fe directly on Si is strongly inhibited. The process that governs growth selectivity is the selective catalytic decomposition of ferrocene on the predeposited catalyst layer. The molecular decomposition products of ferrocene and the resulting Fe enhance the catalytic activity of the metal layer. Ferrocene must be supplied continuously to obtain the longest aligned nanotube arrays. Stopping the flow of ferrocene during growth will terminate growth within 8-11 min, and also result in shorter CNTs. The optimal ferrocene flow is 4-6 mg of ferrocene per hour. With higher ferrocene flow rates, the amount of Fe nanoparticles and the fraction of Fe in the CNTs increases without increasing the length of the CNTs. This feature of the growth process can be used to controllably load CNTs with Fe. Such Fe loaded CNTs could be used for nanomagnetic applications. Film growth is ended by stopping the flow of ferrocene and acetylene. Cooling from the growth temperature is performed in inert gas and hydrogen flow. The sample is unloaded near room temperature.

The addition of extra catalyst extends the CNT thickness from a few hundred microns without ferrocene to several millimeters with the addition of ferrocene. The maximum length of CNTs obtained during a 1 hour growth run was 4.25 mm. Real-time monitoring was not performed during growth. This means that the maximum length may have been reached in a time shorter than an hour if growth termination occurred. The exact time of growth termination can be determined by real-time growth rate measurement techniques.

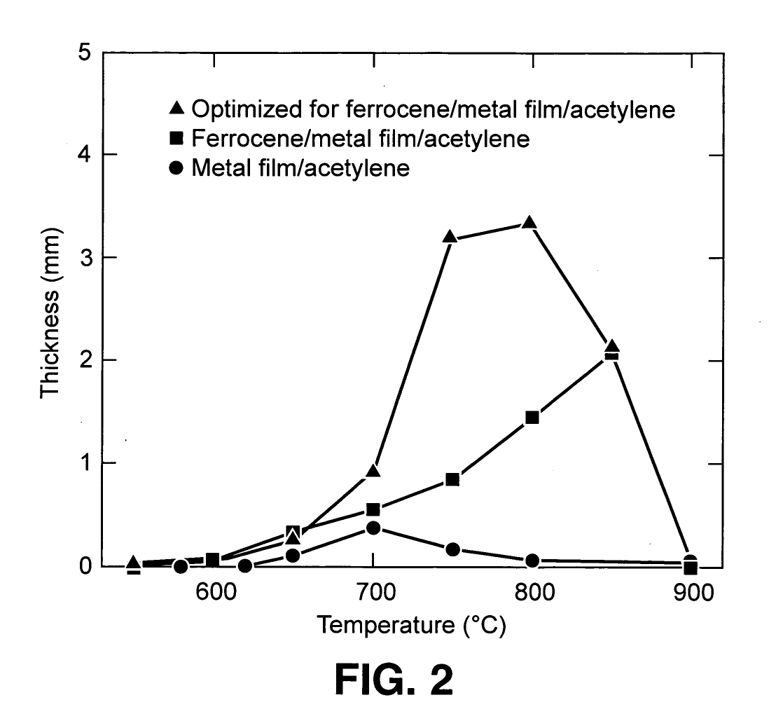

Growth samples were analyzed using SEM and TEM imaging, and Raman spectroscopy. In FIG. 2, the film thickness as a function of the substrate temperature is shown for three different growth conditions. Each data point in these plots represents CNT growth for 1 h.

The thickness of the films was determined from edge-on SEM images of cleaved samples using a special 90° sample holder. The solid dots in FIG. 2 represent growth conditions optimized for maximum CNT film thickness on a given predeposited metal catalyst in terms of the C₂H₂/H₂ flow ratio of 2.9 sccm/100 sccm. Inadvertent variations in the nominal composition of the catalyst layers were found to produce large film-to-film fluctuations in the maximum CNT thickness.

The data series represented by the solid squares shows the film thickness with addition of Fe(C₅H₅)₂ (4 mg/h) under the same gas flow conditions as in the first data set. Note the increase of the film thickness, i.e., growth rate, and the shift of the maximum of the growth curve toward higher temperatures. Further increase in the CNT growth rates shown by the solid triangles was achieved by optimizing the Fe(C₅H₅)₂/C₂H₂ ratio in the feedstock.

With Fe(C₅H₅)₂, CNT growth was no longer dominated by the catalyst layer composition. Instead, the growth rate and the film thickness strongly depended on the amount of Fe(C₅H₅)₂ in the feedstock.

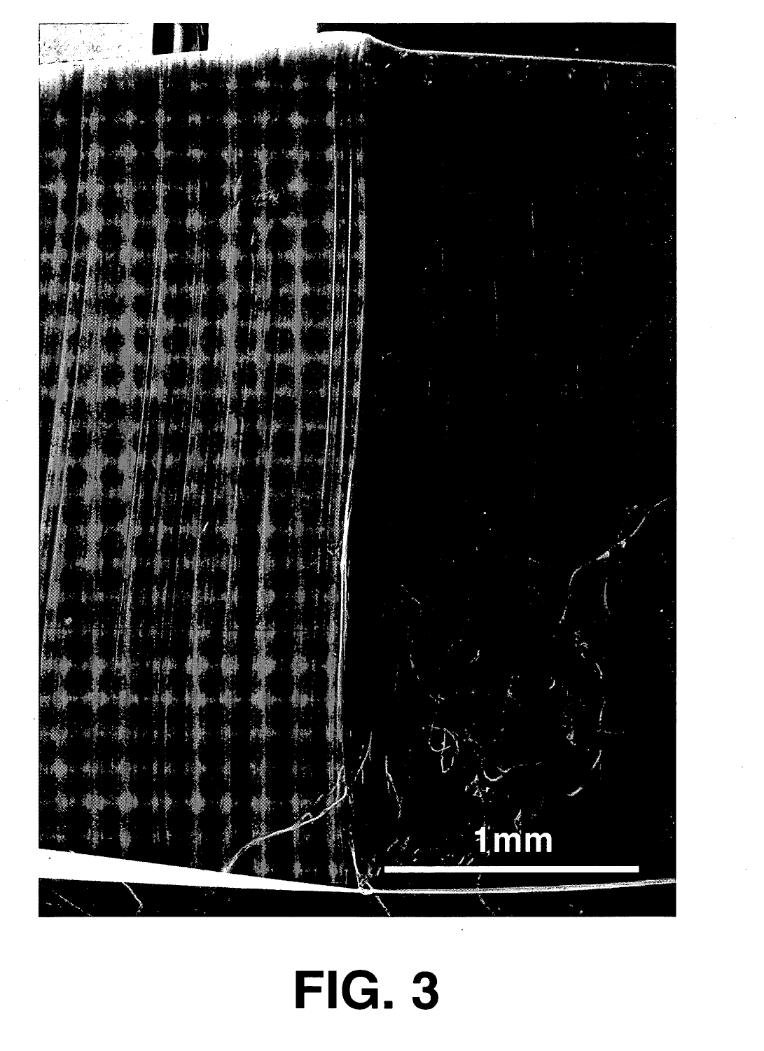

A maximum CNT length of 3.25 mm shown in FIG. 3 was obtained for a 4 mg/h-to-12.4 sccm of the Fe(C₅H₅)₂/C₂H₂ ratio. There is no growth enhancement if the Fe(C₅H₅)₂ flow is shut off before starting the flow of C₂H₂. The full extent of the growth enhancement can be realized only with concurrent acetylene and ferrocene flow.

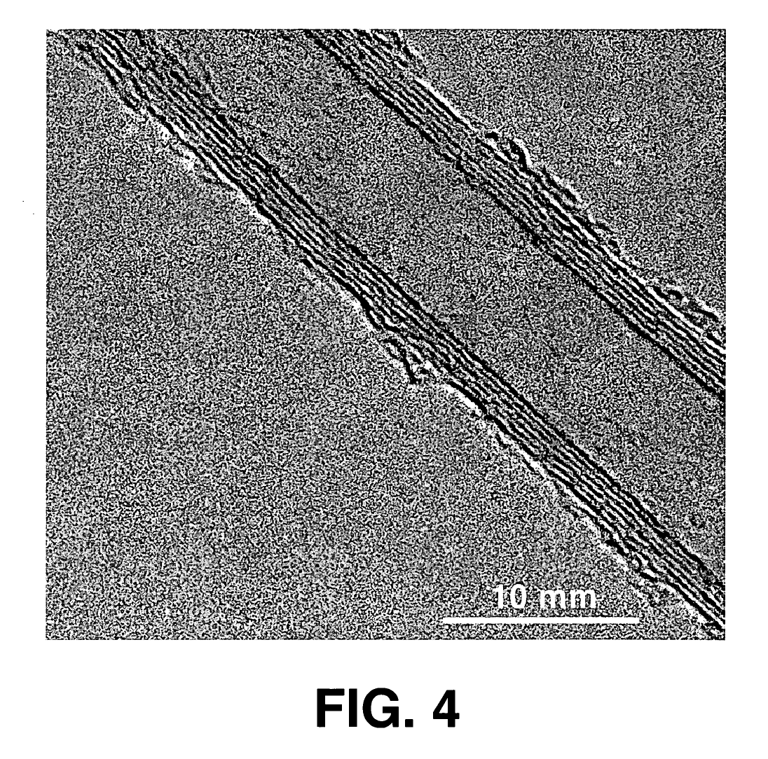

The TEM, SEM, and Raman data reveal no substantial difference in the structure and diameter distribution among the CNTs grown under these three different growth conditions. The temperature dependence of the CNT properties in each particular data set follows similar trends that were outlined previously for growth using the Al/Fe/Mo multilayer. Raman spectroscopy and TEM imaging show that the bulk of the CNT films are comprised of multiwall CNTs. The TEM images from the 3.25 mm thick film reveal a well developed wall structure with four to ten shells (FIG. 4) and a diameter distribution that peaks around 10 nm.

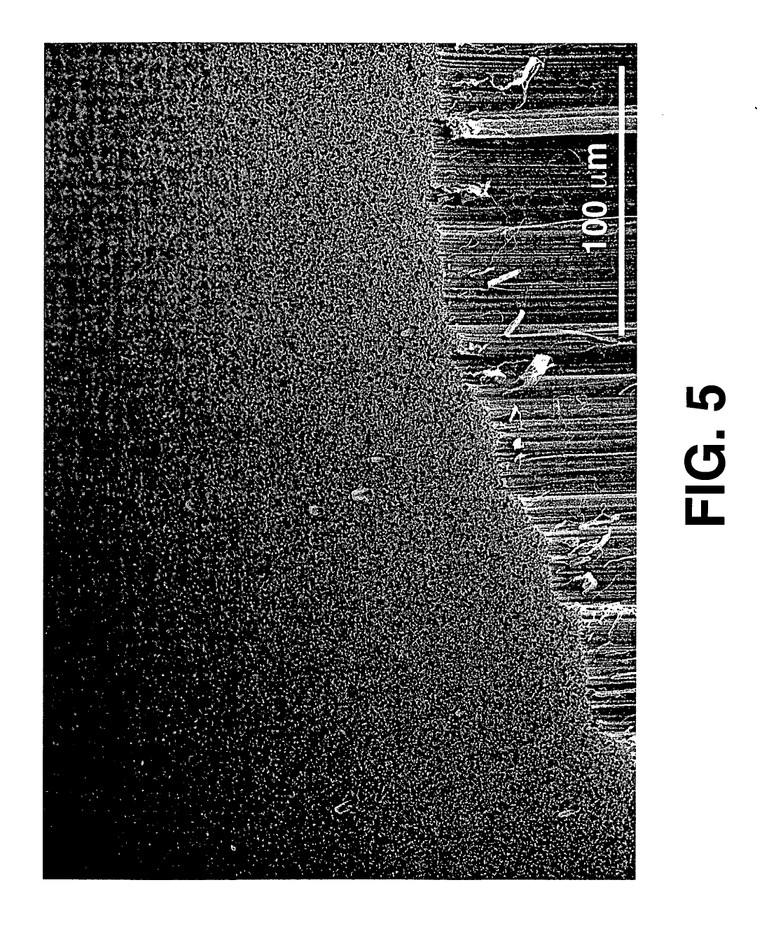

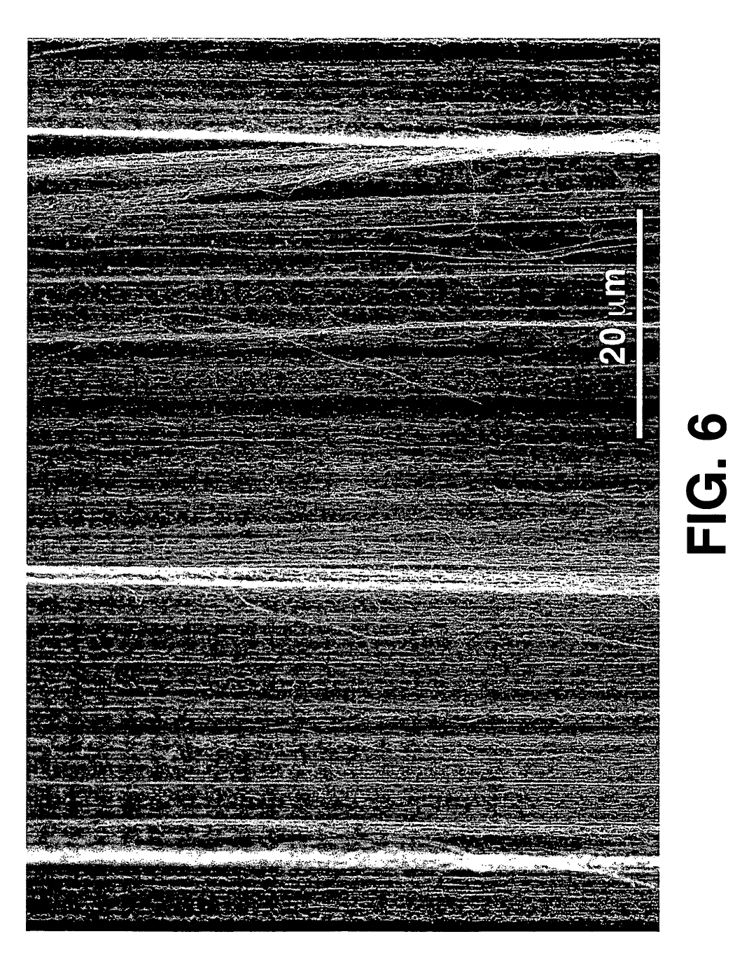

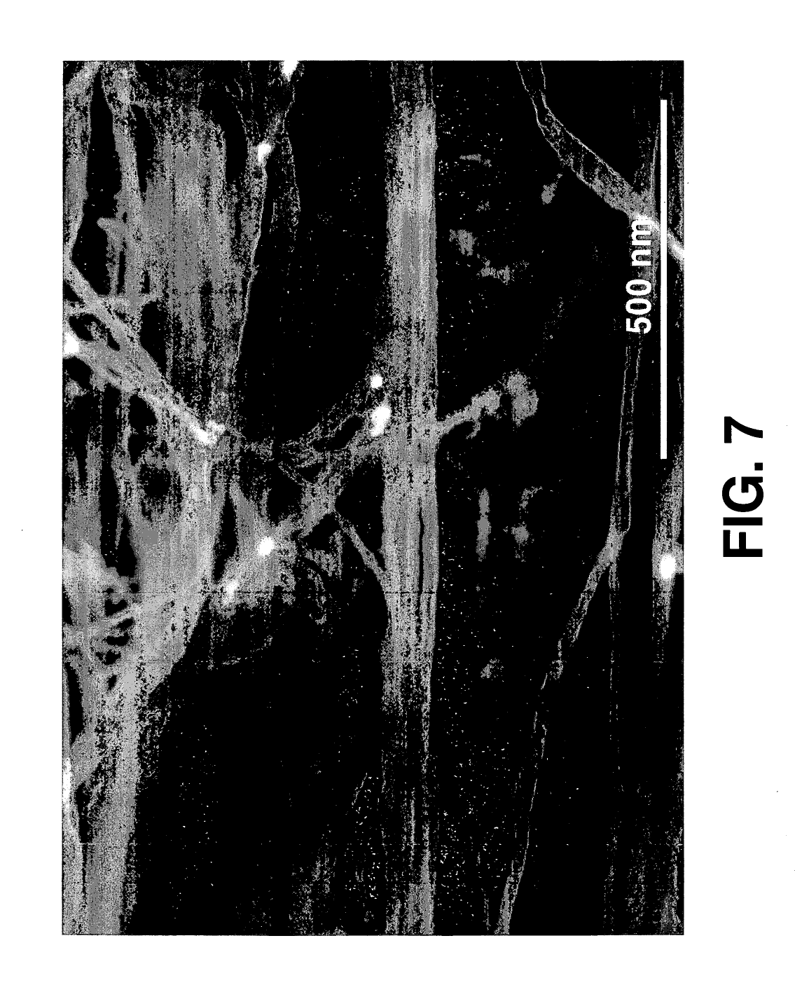

A clear signal corresponding to a single wall (SW) breathing mode was observed in the Raman spectra when the films were scanned from the top. No SW signal was observed when long CNT bundles were scanned edge-on, suggesting that the SWCNTs are located on the top of the films and not intertwined in the films. In contrast with the solvent injection CVD technique, TEM and SEM images for optimal Fe(C₅H₅)₂/C₂H₂ ratio show a substantially reduced number of Fe particles in the root area that were enclosed in carbon or attached to the outside walls of the CNTs. No such particles were observed in the tip area of the CNT films see FIG. 5, nor along the length of the CNTs (FIGS. 6 and 7).

A comparison of the growth curves in FIG. 2 suggests that the addition of Fe(C₅H₅)₂ fundamentally alters the growth mechanism of VACNTs. The small amount of Fe(C₅H₅)₂ corresponding to an equivalent continuous flow rate of 1.5 10⁻² sccm, rules out the possibility that the growth enhancements are supply related. Rather, the reaction products resulting from localized decomposition of Fe(C₅H₅)₂ on the metal layer (but not on Si) act in a way that enhances the catalytic activity of the metal layer toward CNT growth.

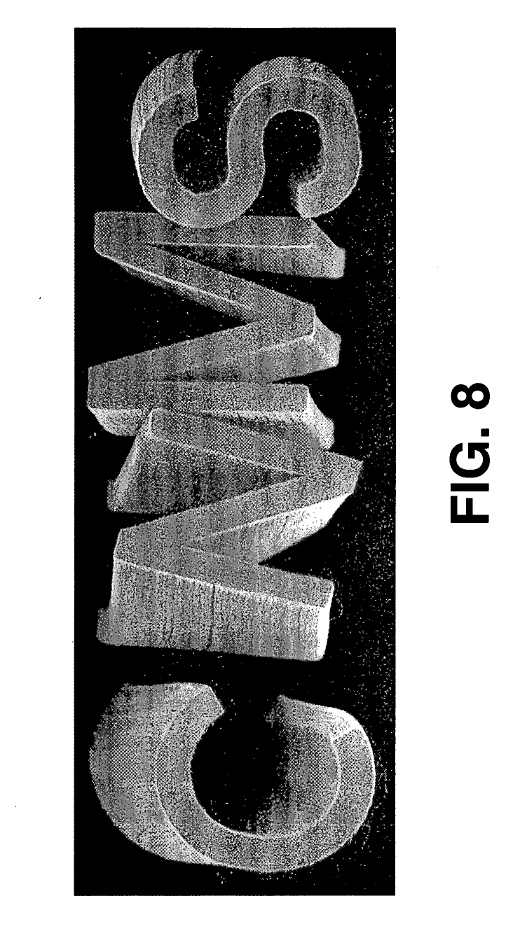

An important aspect of the CVD process is the high degree of selectivity on patterned substrates such as silicon wafers. CNTs are grown only where the metal catalyst layer is deposited. See FIG. 8. The growth selectivity facilitates patterned growth of CNTs, which is useful for direct growth of electrode structures that are needed for sensors, field emitters, and other electronic device applications.

Significant to this invention is the external control provided by the additional catalyst source. The sublimation temperature can be adjusted in real time to change the amount of Fe in the process. The extra Fe that is produced by decomposition of ferrocene interacts with the predeposited catalyst layer and changes the composition of the catalyst layer. By monitoring the growth rate, it can be determined if the amount of ferrocene in the gas stream needs to be adjusted. The amount of ferrocene (vapor pressure) can be increased or decreased by changing the cartridge temperature.

Also significant to this invention is the high degree of selectivity on Si wafers. CNTs were grown only where the metal catalyst layer was deposited. The deposition of Fe from ferrocene is strongly inhibited on Si. The growth selectivity facilitates patterned growth of CNTs. This is useful for the direct growth of electrode structures such as are needed for sensors, field emitters, and other electronic device applications.

A further aspect of this invention is that the controlled ferrocene source converts a bad catalyst into a good catalyst. This feature is related to the difficulties associated with controlling the actual composition of the predeposited catalyst layer. Even though the nominal layer thickness in the multicomponent catalyst layers can be kept constant, very large fluctuations in the growth rates and the thickness of CNT films occur. This inadvertent variation in catalyst composition is suspected to be caused by the systematic and random errors of the thickness monitoring during the catalyst layer deposition. A given catalyst layer can produce very little or no growth compared to another catalyst layer with the same nominal active metal composition. The addition of ferrocene compensates for these fluctuations. With ferrocene, the CNT growth rate is governed by the gas composition and the amount of ferrocene in the feedstock.

A clear practical advantage of vertically aligned arrays of carbon nanotubes is that they are already highly ordered and attached to a substrate. The substrate can be patterned to produce selective area growth for device structures that are used in field emitter arrays. Bulk production of carbon nanotubes can be implemented by harvesting the carbon nanotubes from the substrates. The nanotube material is already aligned, rendering post processing unnecessary.

Application of long CNTs makes spinning long fibers easier and produces stronger fibers. Longer CNTs reduce the number of interconnects (junctions between two CNTs) that are necessary for conducting heat and electricity in long fibers, thereby reducing overall losses.

The invention enables the mass production of long CNTs and thick VA-CNT films. The long CNTs can be used directly in applications, or can serve as raw material for other applications. By extending the nanotube lengths to 1 centimeter, the invention significantly advances the application of CNTs in fibers, filaments, and composites. The growth process that produces long tubes is obviously more economical for bulk material applications.

The long CNTs are especially useful for the production of composites. It is intuitively clear that longer nanotubes can be tangled more easily to produce stronger CNT based composite materials and stronger fibers.

1. A CVD method of producing a carbon nanotube film on a catalyst layer, said method comprising the steps of:
placing a substrate having a catalyst layer in a heatable CVD reactor;
flowing a gas mixture including hydrogen and an inert gas over the catalyst layer;
flowing an externally controllable amount of catalyst precursor gas over the catalyst layer; and
flowing a carbon containing source gas over the catalyst layer.

2. The method of claim 1 wherein the catalyst layer includes a transition metal catalyst, and said catalyst precursor gas includes a transition metal catalyst.

3. The method of claim 2 wherein said transition metal catalyst is iron.

4. The method of claim 1 wherein said catalyst precursor gas is ferrocene.

5. The method of claim 1 wherein the catalyst layer is electrically conducting.

6. The method of claim 1 wherein the catalyst layer is disposed on a silicon substrate.

7. In a heatable CVD reactor that produces a carbon nanotube film on a catalyst layer, apparatus comprising:
an externally controllable sublimation source for delivering a catalyst precursor gas to the catalyst layer.

8. The reactor of claim 7 wherein the catalyst layer includes a transition metal catalyst, and said catalyst precursor gas includes a transition metal catalyst.

9. The reactor of claim 8 wherein said transition metal catalyst is iron.

10. The reactor of claim 7 wherein said catalyst precursor gas is ferrocene.

11. The reactor of claim 7 wherein the catalyst layer is electrically conducting.

12. The reactor of claim 7 wherein the catalyst layer is disposed on a silicon substrate.
